(19) United States
(12) Patent Application Publication
(10) Pub. No.: US 2024/0429914 A1
(43) Pub. Date: Dec. 26, 2024

(54) BOOTSTRAP CHARGE CIRCUIT FOR HALF-BRIDGE TOPOLOGY

(71) Applicant: TEXAS INSTRUMENTS INCORPORATED, Dallas, TX (US)

(72) Inventors: Ding YAN, Shanghai (CN); Fangli GE, Shanghai (CN); Luyang HE, Shanghai (CN)

(21) Appl. No.: 18/341,197

(22) Filed: Jun. 26, 2023

(51) Int. Cl. H03K 17/16; H03K 17/687

(52) U.S. Cl. CPC H03K 17/162; H03K 17/6871

(57) ABSTRACT

In some examples, an apparatus includes a transistor, a semiconductor device, a clamp circuit, and a charge circuit. The transistor has a control terminal, a first terminal, and a second terminal. The second terminal is coupled to a first input voltage terminal. The semiconductor device is coupled between the first terminal and an output terminal. The clamp circuit is coupled between the control terminal and a switch terminal. The charge circuit is coupled between a second input voltage terminal and the control terminal.

### BACKGROUND

In various electronic devices, components are provided that are biased or otherwise receive a control signal for operation. In some instances, a value of that bias or control signal with respect to a value of a second signal causes the component to function in a specified manner. In some applications, a voltage supply available to the component lacks a suitably high voltage with respect to the value of the second signal, thereby preventing the component from operating. To provide the bias or control signal having a higher voltage than available from the voltage supply, the electronic device may include a bootstrap circuit.

### SUMMARY

In some examples, an apparatus includes a transistor, a semiconductor device, a clamp circuit, and a charge circuit. The transistor has a control terminal, a first terminal, and a second terminal. The second terminal is coupled to a first input voltage terminal. The semiconductor device is coupled between the first terminal and an output terminal. The clamp circuit is coupled between the control terminal and a switch terminal. The charge circuit is coupled between a second input voltage terminal and the control terminal.

In some examples, an apparatus includes a first transistor, a clamp circuit, and a charge circuit. The first transistor has a control terminal, a first terminal, and a second terminal. The second terminal is coupled to a first input voltage terminal, and the first terminal is coupled to an output terminal. The clamp circuit is coupled to the control terminal and a switch terminal. The charge circuit has a second transistor, the second transistor having a first terminal, a second terminal, and a control terminal. The second terminal of the second transistor is coupled to the control terminal of the first transistor. The control terminal of the second transistor is coupled to the first terminal of the second transistor.

In some examples, a system includes a power converter and a charge boost circuit. The power converter has a converter input and a switch terminal. The charge boost circuit is coupled between the converter input and a charge boost output terminal. The charge boost circuit includes a transistor having a control terminal, a first terminal, and a second terminal, wherein the second terminal is coupled to the converter input, a semiconductor device coupled between the first terminal and the charge boost output terminal, a clamp circuit coupled between the control terminal and the switch terminal, and a charge circuit coupled between an input voltage terminal and the control terminal.

### BRIEF DESCRIPTION OF THE DRAWINGS

FIG. 1 is a block diagram of a system, in accordance with various examples.

FIG. 2 is a schematic diagram of a bootstrap charge circuit, in accordance with various examples.

FIG. 3 is a diagram of signal waveforms, in accordance with various examples.

FIG. 4 is a schematic diagram of a bootstrap charge circuit, in accordance with various examples.

FIG. 5 is a diagram of signal waveforms, in accordance with various examples.

FIG. 6 is a schematic diagram of a bootstrap charge circuit, in accordance with various examples.

### DETAILED DESCRIPTION

As described above, a bootstrap circuit may facilitate the providing of a signal having a voltage greater than a supply voltage of a circuit. One example application is a power converter. For example, the power converter may receive an input voltage (VIN) for switching via transistors to provide a voltage (VSW) at a switch node (also referred to as a switch terminal). The voltage at the switch node may be converted to an output voltage (VOUT) through one or more other components, such as an inductor. The power converter may include a power supply that provides a voltage VDD. In some circumstances, VDD may be less than VIN such that VDD may be insufficient to maintain a high-side power transistor (HSFET) of the power converter in a conductive state and a signal having a value approximately equal to VIN is provided at the source of the HSFET. To enable normal operation of the HSFET in circumstances in which VDD is less than VIN, a bootstrap circuit may be implemented. Some examples of a bootstrap circuit include a bootstrap capacitor that stores charge and provides that charge at the gate of the HSFET to supplement VDD such that a voltage provided at the gate of the HSFET is greater than VIN. Various architectures are available for a bootstrap charge circuit to charge the bootstrap capacitor. However, at least some of these bootstrap charge circuits include limitations that increase a surface area occupied by the bootstrap charge circuit, limit a rate of charge of the bootstrap capacitor, etc.

Examples of this description provide for a bootstrap charge circuit for charging a bootstrap capacitor. In some examples, the bootstrap charge circuit and bootstrap capacitor are implemented in a device including a power converter. For example, the bootstrap capacitor may be coupled between a gate of a HSFET and a switch node of the power converter to supplement a control signal provided at the gate of the HSFET. The bootstrap charge circuit may be coupled to the bootstrap capacitor to charge the bootstrap capacitor. In some examples, the bootstrap charge circuit may be included in a power controller coupled to the power converter to control operation of the power converter.

FIG. 1 is a block diagram of a system 100, in accordance with various examples. The system 100 may be generally representative of any device or system that includes a power converter. In various examples, the system 100 may be representative of an electronic device (e.g., a laptop computer, a desktop computer, a server computer, a smartphone, a wearable device, a health monitoring device, a wireless access point, or the like), an automobile, an aircraft, a spacecraft (e.g., satellite), or any other device including a power converter.

In an example, the system 100 includes a power converter 102, a controller 104, a power source 106, and a load 108. The controller 104 controls the power converter 102 to switch power from the power source 106 to the load 108. In examples in which the power converter 102 is a step-down power converter, the power converter 102 receives an input voltage (VIN) from the power source 106 having a first value and provides an output voltage (VOUT) to the load 108 having a second value, where the second value is less than the first value. In other examples, the power converter 102 may also, or alternatively, be a step-up power converter (such as a boost converter or buck-boost converter). In an example, the power converter 102 includes a high-side (HS) power transistor 110 and a low-side (LS) power transistor 112. As shown in FIG. 1, the power converter 102 may be referred to as a half-bridge converter, or as having a half-bridge topography or architecture. The HS power transistor 110 has a drain coupled to the power source 106, a gate coupled to the controller 104, and a drain coupled to a switch node 114. The LS power transistor 112 has a drain coupled to the switch node 114, a gate coupled to the controller 104, and a source coupled to a ground terminal 116. Although not shown in FIG. 1, in some examples, the controller 104 includes drivers coupled to the gates of the HS power transistor 110 and LS power transistor 112, while in other examples, drivers are coupled between respective outputs of the controller 104 and gates of the HS power transistor 110 and LS power transistor 112. In an example, the controller 104 includes a bootstrap circuit 118 coupled to the gate of the HS power transistor 110 and a bootstrap charge circuit 120 coupled to the power source 106 and the bootstrap circuit 118.

The controller 104 provides a control signal (HSctrl) that controls the HS power transistor 110 and a control signal (LSctrl) that controls the LS power transistor 112 to switch on and off at a switching frequency determined to cause VOUT to have a programmed value, such as based on a target or reference value received by the controller 104. For example, the greater the switching frequency, the larger the value of VOUT and the smaller the switching frequency, the smaller the value of VOUT. Many different control schemes or methodologies may be suitable for controlling the power converter 102 (e.g., the HS power transistor 110 and the LS power transistor 112), and the controller 104 may take various architectural (e.g., hardware or structural) forms to implement these control schemes, the scope of which is not limited herein.

To cause the HS power transistor 110 to become, and stay, conductive, HSctrl is provided having a value sufficiently greater (e.g., a gate-to-source threshold voltage greater) than VIN. However, for some applications of the system 100, VIN may have a value greater than that of HSctrl, which may prevent the controller 104 from controlling the HS power transistor 110 to become conductive. To mitigate this possibility, the bootstrap circuit 118 augments a value of HSctrl. For example, some implementations of the bootstrap circuit 118 include a bootstrap capacitor (not shown) that stores charges and provides that charge at the gate of the HS power transistor 110, adding to a value of HSctrl, causing the HS power transistor 110 to become, or remain, conductive. The bootstrap circuit 118 may charge and discharge periodically, such as discharging responsive to HSctrl having an asserted value and charging responsive to HSctrl having a deasserted value (or, LSctrl having an asserted value). The bootstrap charge circuit 120 couples to the bootstrap circuit 118 and is configured to charge the bootstrap circuit 118. For example, responsive to HSctrl becoming deasserted and LSctrl becoming asserted, the switch node 114 is pulled down through the LS power transistor 112 such that VSW is approximately equal to a ground voltage potential provided at the ground terminal 116. Responsive to VSW decreasing in value, the bootstrap charge circuit 120 charges the bootstrap circuit 118.

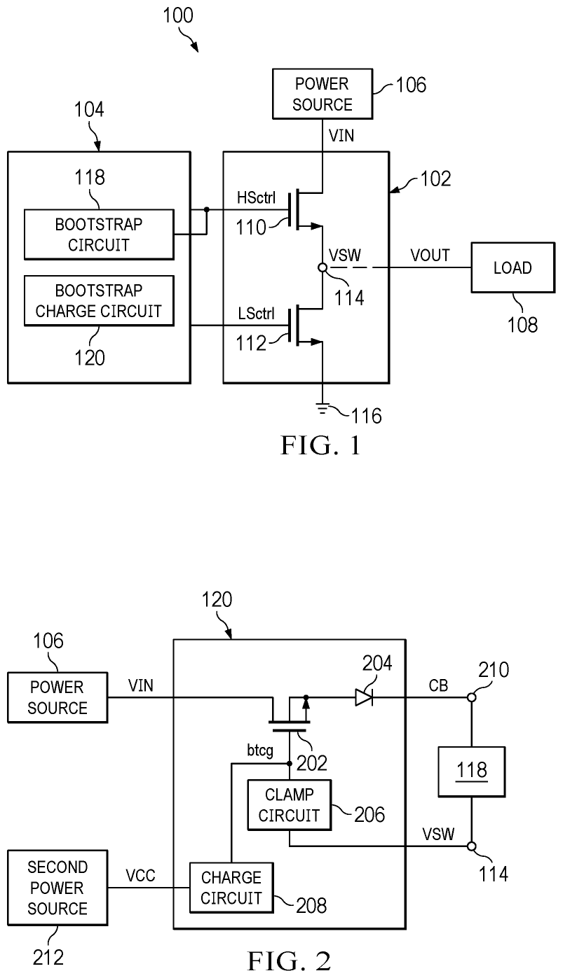

FIG. 2 is a schematic diagram of the bootstrap charge circuit 120, in accordance with various examples. In an example, the bootstrap charge circuit 120 includes a transistor 202, a diode 204, a clamp circuit 206, and a charge circuit 208. In some examples, the clamp circuit 206 is implemented as a Zener diode. In other examples, the clamp circuit 206 is any circuit capable of limiting a voltage to a programmed or predefined value. In some examples, the charge circuit 208 is implemented as a diode, or as a diode-coupled transistor. In other examples, the charge circuit 208 is implemented as a charge pump of any suitable architecture. In some examples, the transistor 202 is a n-channel metal oxide semiconductor (NMOS) transistor.

In an example architecture of the bootstrap charge circuit 120 of FIG. 2, the transistor 202 has a drain coupled to the power source 106 to receive VIN, a gate, and a source. In some examples, a body or bulk of the transistor 202 is coupled to the source of the transistor 202. In other examples, such as examples in which the diode 204 is omitted, the body of the transistor 202 is coupled to the switch node 114. The diode 204 has an anode coupled to the source of the transistor 202 and a cathode coupled to a charge boost terminal 210. In some examples, the bootstrap circuit 118 is coupled between the terminal 210 and the switch node 114. The clamp circuit 206 is coupled between the switch node 114 and the gate of the transistor 202. The charge circuit 208 is coupled between a second power source 212 and the gate of the transistor 202. Although shown in FIG. 2 as a diode, in some examples, the diode 204 is implemented as a transistor having a drain coupled to the source of the transistor 202, a source coupled to the terminal 210, and a gate coupled to the switch node 114 or which receives a signal that is an inverse of LSctrl.

In an example of operation of the bootstrap charge circuit 120 of FIG. 2, a parasitic capacitance of the transistor 202 causes a voltage provided at the gate of the transistor 202 (btcg) minus VSW to move in an opposite direction as VSW. For example, as VSW decreases, btcg minus VSW increases, turning on the transistor 202. In an example, a value of bteg is limited by a clamp voltage of the clamp circuit 206. For example, in implementations in which the clamp circuit 206 is a Zener diode, bteg is limited, or clamped, to a breakdown voltage of the Zener diode. Responsive to the transistor 202 turning on, the transistor 202 and diode 204 provide a signal (CB) at the terminal 210 having a voltage less than or approximately equal to the clamp voltage of the clamp circuit 206 minus a threshold voltage of the transistor 202, minus a forward diode voltage drop of the diode 204. In some examples, the bootstrap charge circuit 120 charges the bootstrap circuit 118 with CB. In an example, btcg is in a low voltage domain, causing the source of the transistor 202 to also be in the low voltage domain and provide a signal to the diode 204 that is in the low voltage domain. As a result, the diode 204 may be implemented as a low voltage device. Therefore, the diode 204 may occupy a smaller space and have a smaller reverse recovery charge than other diodes, such as high voltage diodes. As used herein, the low voltage domain is relative to VSW. In contrast, signals relative to the ground voltage potential may be high voltage domain signals.

In some examples, the charge circuit 208 provides btcg based on a voltage provided by the second power source 212. For example, responsive to VIN having a value less than the clamp voltage of the clamp circuit 206, a voltage provided by the second power source 212 (Vcc) is greater than btcg. In such an example, the charge circuit 208 provides bteg having a value approximately equal to Vcc (e.g., minus any voltage drop associated with the charge circuit 208) such that a voltage difference across the clamp circuit 206 (e.g., a value of btcg minus VSW) is approximately equal to the lesser of the clamp voltage of the clamp circuit 206 or the voltage provided by the charge circuit 208.

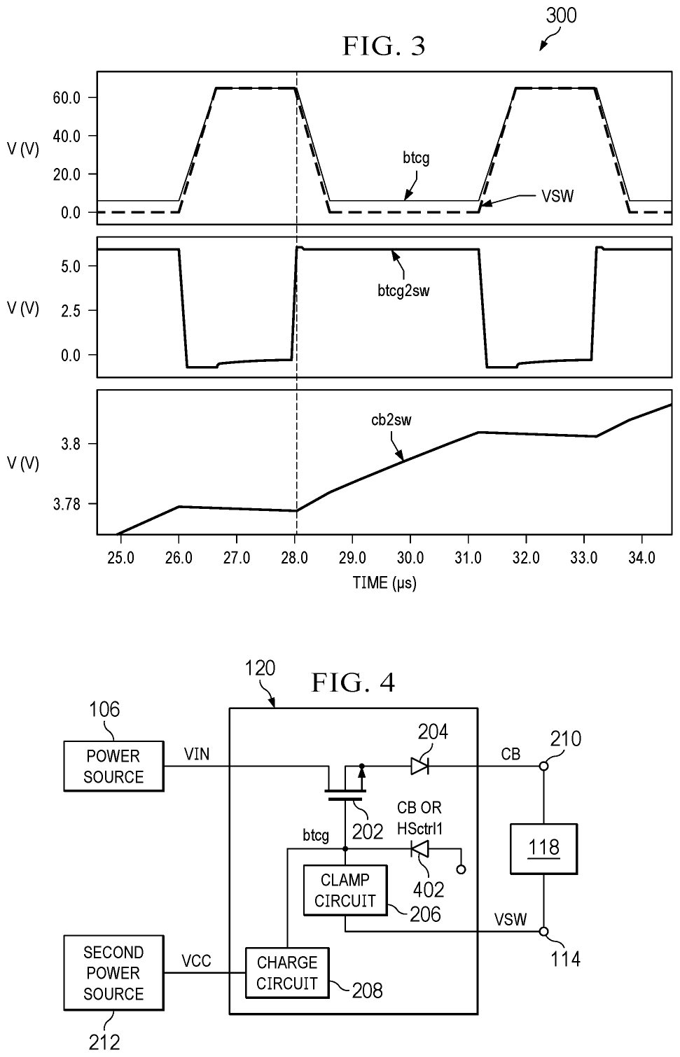

FIG. 3 is a diagram 300 of signal waveforms, in accordance with various examples. In an example, the diagram 300 includes btcg. VSW, a signal (btcg2sw) showing a difference in value between btcg and VSW, and a signal (cb2SW) showing a difference in value between CB and VSW. At least some of the signals of the diagram 300, such as btg and VSW, may be provided in the bootstrap charge circuit 120 of FIG. 2. The signals of the diagram 300 are shown having a vertical axis representative of voltage in units of volts (V) and a horizontal axis representative of time in units of microseconds (μs).

As shown in FIG. 3, capacitive coupling between the drain and gate of the transistor 202 holds btcg at a value greater than VSW while VSW has a deasserted value, as well as while VSW transitions from an asserted value to the deasserted value, as described above. Responsive to btcg2sw increasing in value (e.g., btcg being held at a higher voltage than VSW), the transistor 202 is held on in a conductive state such that current flows through the transistor 202 to the terminal 210 and cb2sw increases in value. In some examples, cb2sw is representative of a charge stored by the bootstrap circuit 118 (e.g., a difference in voltage across the terminal 210 and the switch node 114). In some implementations of the bootstrap charge circuit 120, cb2sw has a value less than or equal to the clamp voltage of the clamp circuit 206 minus a threshold voltage of the transistor 202. Thus, as shown in the diagram 300, responsive to VSW having a deasserted value, or transitioning from an asserted value to a deasserted value, the bootstrap circuit 118 is charged.

FIG. 4 is a schematic diagram of the bootstrap charge circuit 120, in accordance with various examples. The bootstrap charge circuit 120 of FIG. 4 includes components of the bootstrap charge circuit 120 of FIG. 2, which are coupled and operate in a substantially similar manner. As such, description of these components is not repeated with respect to FIG. 4. In an example, the bootstrap charge circuit 120 also includes a diode 402 having a cathode coupled to the gate of the transistor 202, and having an anode. In some examples, the anode of the diode 402 is coupled to the terminal 210. In other examples, the anode of the diode 402 is coupled to the gate of the HS power transistor 110 of FIG. 1.

In an example of operation of the bootstrap charge circuit 120 of FIG. 4, the diode 402 pre-charges the gate of the transistor 202. For example, responsive to bteg having a value less than CB or HSctrl, current flows through the diode 402 in a forward direction to the gate of the transistor 202, increasing a value of btcg. Responsive to bteg increasing in value to be within a threshold amount of CB or HSctrl, the diode 402 ceases conducting current in a forward direction to the gate of the transistor 202. Thus, in some examples, the diode 402 functions as a charge pump to charge the gate of the transistor 202 and btcg. In this way, the value of btcg may be increased by the diode 402, maintaining the transistor 202 in a conductive state despite a decreasing value of VIN. Maintaining the transistor 202 in the conductive state for a greater amount of time may cause the bootstrap circuit 118 to charge to a larger voltage than in the absence of the diode 402. In some examples, the diode 402 may be considered a high-side charge pump through which current flows through in a forward direction to the gate of the transistor 202 while VSW has an asserted value (e.g., is approximately equal to VIN). Correspondingly, the charge circuit 208 may be considered a low-side charge pump through which current flows through in a forward direction to the gate of the transistor 202 while VSW has a deasserted value.

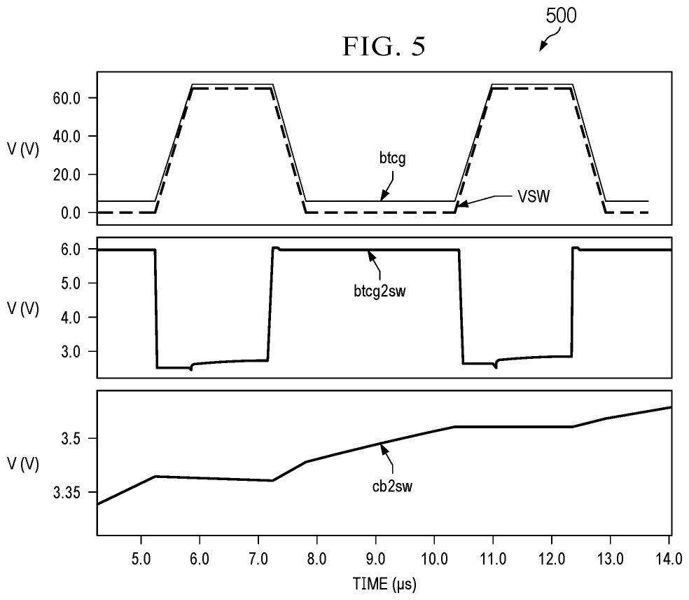

FIG. 5 is a diagram 500 of signal waveforms, in accordance with various examples. In an example, the diagram 500 includes btcg. VSW, a signal (btcg2sw) showing a difference in value between btcg and VSW, and a signal (cb2sw) showing a difference in value between CB and VSW. At least some of the signals of the diagram 500, such as bteg and VSW, may be provided in the bootstrap charge circuit 120 of FIG. 4. The signals of the diagram 500 are shown having a vertical axis representative of voltage in units of V and a horizontal axis representative of time in units of us.

As shown in FIG. 5, capacitive coupling between the drain and gate of the transistor 202 holds bteg at a value greater than VSW while VSW has a deasserted value, as well as while VSW transitions from an asserted value to the deasserted value, as described above. The value of btcg is further increased with respect to VSW by approximately CB minus one diode voltage of the diode 402. Responsive to btcg2sw increasing in value (e.g., btcg being held at a higher voltage than VSW), the transistor 202 is held on in a conductive state such that current flows through the transistor 202 to the terminal 210 and cb2sw increases in value. In some examples, cb2sw is representative of a charge stored by the bootstrap circuit 118 (e.g., a difference in voltage across the terminal 210 and the switch node 114). Thus, as shown in the diagram 500, responsive to VSW having a deasserted value, or transitioning from an asserted value to a deasserted value, the bootstrap circuit 118 is charged.

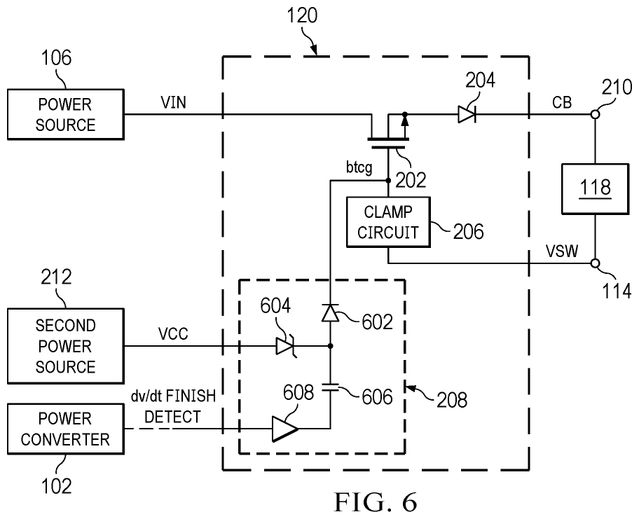

FIG. 6 is a schematic diagram of the bootstrap charge circuit 120, in accordance with various examples. The bootstrap charge circuit 120 of FIG. 6 includes components of the bootstrap charge circuit 120 of FIG. 2, which are coupled and operate in a substantially similar manner. As such, description of these components is not repeated with respect to FIG. 6. In an example, the charge circuit 208 includes a diode 602, a diode 604, a capacitor 606, and an buffer 608. Although not shown in FIG. 6, in some examples, the bootstrap charge circuit 120 includes the diode 402, as described above. Although shown in FIG. 6 as a diode, in some examples, the diode 602 is implemented as a diode-coupled transistor. In some examples, the diode 604 is implemented as a Zener diode. In other examples, the diode 604 is implemented as a clamp circuit capable of providing current and limiting a voltage to a programmed or predefined value. In some examples, the charge circuit 208 includes a clamp circuit (not shown) coupled in parallel with the capacitor 606 to limit a voltage provided across the capacitor 606.

In an example architecture of the bootstrap charge circuit 120 of FIG. 6, the diode 602 has a cathode coupled to the gate of the transistor 202, and has an anode. The diode 604 has an anode coupled to the second power source 212, and has a cathode coupled to the anode of the diode 602. The capacitor 606 has a first terminal coupled to the anode of the diode 602, and has a second terminal. The buffer 608 has an input at which a dv/dt finish signal is provided, and an output coupled to the second terminal of the capacitor 606. In some examples, the bootstrap charge circuit 120 includes a sensor or circuit (not shown) coupled to the power converter 102 and which provides the dv/dt finish signal. In an example, the dv/dt signal indicates that commutation of the LS power transistor 112 has completed and VSW has a deasserted value (e.g., VSW is approximately equal to the ground voltage potential). In other examples, the buffer 608 receives a delayed representation of LSctrl rather than the dv/dt finish signal.

In an example of operation of the bootstrap charge circuit 120 of FIG. 6, responsive to the dv/dt finish signal having an asserted value, thereby indicating that VSW is approximately equal to the ground voltage potential, the buffer 608 provides a signal at the second terminal of the capacitor 606 having a deasserted value, or a value approximately equal to the ground voltage potential. The diode 604 provides current to the first terminal of the capacitor 606, charging the capacitor and causing a capacitor voltage to be provided across the first and second terminals of the capacitor 606. In an example, the capacitor voltage is limited, or clamped, according to a breakdown voltage of the diode 604. The capacitor voltage is provided by the diode 602 to the gate of the transistor 202, increasing the value of btcg, as described above herein. In an example, the charge circuit 208 of the bootstrap charge circuit 120 of FIG. 6 provides the capacitor voltage to the gate of the transistor 202 until the dv/dt finish signal has a deasserted value (e.g., indicating that VSW no longer has a deasserted value), or bteg increases to exceed the capacitor voltage (e.g., such as via drain-to-gate capacitive coupling of the transistor 202).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. An apparatus, comprising:
a transistor having a control terminal, a first terminal, and a second terminal, wherein the second terminal is coupled to a first input voltage terminal;
a semiconductor device coupled between the first terminal and an output terminal;
a clamp circuit coupled between the control terminal and a switch terminal; and
a charge circuit coupled between a second input voltage terminal and the control terminal.

2. The apparatus of claim 1, wherein the semiconductor device is a diode having an anode and a cathode, wherein the anode is coupled to the first terminal and the cathode is coupled to the output terminal.

3. The apparatus of claim 1, wherein:
the transistor is a first transistor; and
the semiconductor device is a second transistor having a control terminal, a first terminal, and a second terminal, wherein the second terminal of the second transistor is coupled to the first terminal of the second transistor, the first terminal of the second transistor is coupled to the output terminal, and the control terminal of the second transistor is coupled to the switch terminal.

4. The apparatus of claim 1, further comprising a capacitor coupled between the output terminal and the switch terminal.

5. The apparatus of claim 1, wherein the clamp circuit includes a Zener diode having a Zener anode and a Zener cathode, wherein the Zener anode is coupled to the switch terminal and the Zener cathode is coupled to the control terminal of the transistor.

6. The apparatus of claim 1, wherein:
the transistor is a first transistor; and
the charge circuit includes a second transistor having a control terminal, a first terminal, and a second terminal, wherein the second terminal of the second transistor is coupled to the control terminal of the first transistor, the first terminal of the second transistor is coupled to the second input voltage terminal, and the control terminal of the second transistor is coupled to the second input voltage terminal.

7. The apparatus of claim 1, wherein the charge circuit includes a charge pump.

8. The apparatus of claim 1, further comprising a diode having an anode and a cathode, wherein the cathode is coupled to the control terminal and the anode is coupled to the switch terminal.

9. An apparatus, comprising:
a first transistor having a control terminal, a first terminal, and a second terminal, wherein the second terminal is coupled to a first input voltage terminal, and the first terminal is coupled to an output terminal;
a clamp circuit coupled to the control terminal and a switch terminal; and
a charge circuit having a second transistor, the second transistor having a first terminal, a second terminal, and a control terminal, the second terminal of the second transistor coupled to the control terminal of the first transistor, and the control terminal of the second transistor coupled to the first terminal of the second transistor.

10. The apparatus of claim 9, wherein the first terminal of the second transistor is coupled to a second input voltage terminal.

11. The apparatus of claim 9, wherein the charge circuit includes:
a diode having an anode and a cathode, the cathode coupled to the first terminal of the second transistor and the anode coupled to a second input voltage terminal;
a capacitor having first and second terminals, the first terminal of the capacitor coupled to the first terminal of the second transistor; and
a buffer having a buffer input and a buffer output, the buffer output coupled to the second terminal of the capacitor.

12. The apparatus of claim 9, further comprising:
a half-bridge power converter having a converter input and a switch terminal, wherein the converter input is coupled to the second terminal of the first transistor; and
a capacitor coupled between the switch terminal and the first terminal of the first transistor.

13. The apparatus of claim 12, further comprising a third transistor having a control terminal, a first terminal, and a second terminal, the second terminal of the third transistor coupled to the first terminal of the first transistor, the first terminal of the third transistor coupled to the output terminal, and the control terminal of the third transistor coupled to the switch terminal.

14. A system, comprising:
a power converter having a converter input and a switch terminal; and
a charge boost circuit coupled between the converter input and a charge boost output terminal, wherein the charge boost circuit includes:
a transistor having a control terminal, a first terminal, and a second terminal, wherein the second terminal is coupled to the converter input;
a semiconductor device coupled between the first terminal and the charge boost output terminal;
a clamp circuit coupled between the control terminal and the switch terminal; and
a charge circuit coupled between an input voltage terminal and the control terminal.

15. The system of claim 14, wherein the semiconductor device is a diode having an anode and a cathode, wherein the anode is coupled to the first terminal and the cathode is coupled to the charge boost output terminal.

16. The system of claim 14, wherein:
the transistor is a first transistor; and
the semiconductor device is a second transistor having a control terminal, a first terminal, and a second terminal, wherein the second terminal of the second transistor is coupled to the first terminal of the first transistor, the first terminal of the second transistor is coupled to the charge boost output terminal, and the control terminal of the second transistor is coupled to the first terminal of the second transistor.

17. The system of claim 14, further comprising a capacitor coupled between the charge boost output terminal and the switch terminal.

18. The system of claim 14, wherein the clamp circuit includes a Zener diode having a Zener anode and a Zener cathode, wherein the Zener anode is coupled to the switch terminal and the Zener cathode is coupled to the control terminal.

19. The system of claim 14, wherein the charge circuit includes a charge pump.

20. The system of claim 14, wherein the charge boost circuit includes an anode and a cathode, wherein the cathode is coupled to the control terminal and the anode is coupled to the charge boost output terminal.
